(19) United States
(12) Patent Application Publication
(10) Pub. No.: US 2026/0143866 A1
(43) Pub. Date: May 21, 2026

(54) LIGHT-EMITTING DEVICE, DISPLAY DEVICE COMPRISING THE SAME, AND METHOD OF FABRICATING THE LIGHT-EMITTING DEVICE

(71) Applicants: SAMSUNG ELECTRONICS CO., LTD., Suwon-si (KR); CHUNGBUK NATIONAL UNIVERSITY INDUSTRY-ACADEMIC COOPERATION FOUNDATION, Cheongju-si (KR)

(72) Inventors: Youngtek OH, Suwon-si (KR); Jaewook JEONG, Cheongju-si (KR); Kyungwook HWANG, Suwon-si (KR); Dongchul SHIN, Suwon-si (KR)

(73) Assignees: SAMSUNG ELECTRONICS CO., LTD., Suwon-si (KR); CHUNGBUK NATIONAL UNIVERSITY INDUSTRY-ACADEMIC COOPERATION FOUNDATION, Cheongji-si (KR)

(21) Appl. No.: 19/213,560

(22) Filed: May 20, 2025

(30) Foreign Application Priority Data
Nov. 19, 2024 (KR) 10-2024-0165640

(51) Int. Cl. H10H 20/816; H10H 20/01; H10H 20/812

(52) U.S. Cl. CPC H10H 20/8162; H10H 20/013; H10H 20/812

(57) ABSTRACT

Provided is a light-emitting device including a plurality of light emission structures configured to emit light of different colors, wherein each light emission structure of the plurality of light emission structures includes a first conductive semiconductor layer, an active layer having a quantum well structure, and a second conductive semiconductor layer, and a current blocking layer between at least one pair of adjacent light emission structures of the plurality of light emission structures, the current blocking layer including at least one PN junction layer, wherein the at least one PN junction layer includes a first blocking semiconductor layer doped with a first conductive impurity at a first concentration and a second blocking semiconductor layer on the first blocking semiconductor layer and doped with a second conductive impurity at a second concentration.

### CROSS-REFERENCE TO RELATED APPLICATION

This application claims priority to Korean Patent Application No. 10-2024-0165640, filed on Nov. 19, 2024, in the Korean Intellectual Property Office, the disclosure of which is incorporated by reference herein in its entirety.

### BACKGROUND

### 1. Field

Embodiments of the present disclosure relate to a light-emitting device, a display device including the light-emitting device, and a method of fabricating the light-emitting device.

### 2. Description of Related Art

Light-emitting devices, e.g., light-emitting diodes (LED), have been known as next-generation light sources that have advantages such as longer lifespan, low power consumption, fast response speed, or eco-friendliness compared to conventional light sources. Due to such advantages, the industrial demand for light-emitting diodes has increased. LEDs have been commonly applied and used for various products, such as lighting devices or display devices.

In recent years, ultra-small LEDs in micro or nano units have been developed, and these are referred to as microLEDs. MicroLEDs have been applied to relatively large display devices, such as televisions, and further applications in compact display devices, such as displays for augmented reality (AR) devices, have been attempted. MicroLEDs applicable to compact display devices may have a vertical array structure in which RGB sub-pixels are vertically stacked. In microLEDs having such a vertical array structure, a leakage current may occur between RGB sub-pixels.

### SUMMARY

One or more embodiments provide a light-emitting device with reduced leakage current between vertically-stacked sub-pixels, and a display device including the light-emitting device.

Additional aspects will be set forth in part in the description which follows and, in part, will be apparent from the description, or may be learned by practice of one or more embodiments.

According to an aspect of one or more embodiments, there is provided a light-emitting device including a plurality of light emission structures configured to emit light of different colors, wherein each light emission structure of the plurality of light emission structures includes a first conductive semiconductor layer, an active layer having a quantum well structure, and a second conductive semiconductor layer, and a current blocking layer between at least one pair of adjacent light emission structures of the plurality of light emission structures, the current blocking layer including at least one PN junction layer, wherein the at least one PN junction layer includes a first blocking semiconductor layer doped with a first conductive impurity at a first concentration and a second blocking semiconductor layer on the first blocking semiconductor layer and doped with a second conductive impurity at a second concentration.

The light-emitting device may further include a plurality of first electrodes in contact with first conductive semiconductor layers included in the plurality of light emission structures, respectively, and a plurality of second electrodes in contact with second conductive semiconductor layers included in the plurality of light emission structures, respectively, wherein the current blocking layer is spaced apart from the plurality of first electrodes and the plurality of second electrodes.

A doping concentration of the first conductive impurity in the first blocking semiconductor layer and a doping concentration of the second conductive impurity in the second blocking semiconductor layer may be each 1×10¹⁷ cm⁻³ to 1×10²⁰cm⁻³.

A thickness of the first blocking semiconductor layer may be less than or equal to 500 nm.

A thickness of the second blocking semiconductor layer may be less than or equal to 500 nm.

The at least one PN junction layer may further include a plurality of PN junction layers.

The light-emitting device may further include a depletion reduction layer that includes a semiconductor layer doped with the second conductive impurity at the second concentration, wherein the current blocking layer may be on the depletion reduction layer.

A plurality of PN junction layers may be on the depletion reduction layer.

A doping concentration of the second conductive impurity in the depletion reduction layer may be 1×10¹⁷ cm⁻³ to 1×10²⁰cm⁻³.

A thickness of the depletion reduction layer may be less than or equal to 500 nm.

The light-emitting device may further include a plurality of first electrodes in contact with first conductive semiconductor layers included in the plurality of light emission structures, respectively, and a plurality of second electrodes in contact with second conductive semiconductor layers included in the plurality of light emission structures, respectively, wherein the depletion reduction layer may be spaced apart from the plurality of first electrodes and the plurality of second electrodes.

The first blocking semiconductor layer may include a semiconductor material same as a semiconductor material of the first conductive semiconductor layer.

The second blocking semiconductor layer may include a semiconductor material same as a semiconductor material of the second conductive semiconductor layer.

According to another aspect of one or more embodiments provide a method of fabricating a light-emitting device, the method including forming a first light emission structure on a substrate, the first light emission structure including a first conductive semiconductor layer, an active layer, and a second conductive semiconductor layer, forming at least one first PN junction layer on the first light emission structure, the at least one first PN junction layer including a first blocking semiconductor layer doped with a first conductive impurity at a first concentration and a second blocking semiconductor layer doped with a second conductive impurity at a second concentration, and forming a second light emission structure on the at least one first PN junction layer, the second light emission structure including a first conductive semiconductor layer, an active layer, and a second conductive semiconductor layer.

A doping concentration of the first conductive impurity in the first blocking semiconductor layer and a doping concentration of the second conductive impurity in the second blocking semiconductor layer may be 1×10¹⁷ cm⁻³ to 1×10²⁰cm⁻³.

The method may further include forming a depletion reduction layer on the first light emission structure, the depletion reduction layer including a semiconductor material doped with the second conductive impurity at the first concentration, wherein the at least one first PN junction layer is formed on the depletion reduction layer.

A doping concentration of the second conductive impurity in the depletion reduction layer may be 1×10¹⁷ cm⁻³ to 1×10²⁰cm⁻³.

According to still another aspect of one or more embodiments provide a display device including a display panel including a plurality of light-emitting devices and a driving circuit configured to switch the plurality of light-emitting devices on and off, and at least one processor configured to input an on-off switching signal of the plurality of light-emitting devices to the driving circuit based on an image signal, wherein each of the plurality of light-emitting devices includes a plurality of light emission structures configured to emit light of different colors, wherein each of the plurality of light emission structures includes a first conductive semiconductor layer, an active layer having a quantum well structure, and a second conductive semiconductor layer, and a current blocking layer between at least one pair of adjacent light emission structures of the plurality of light emission structures, the current blocking layer including at least one PN junction layer, wherein the at least one PN junction layer includes a first blocking semiconductor layer doped with a first conductive impurity at a first concentration, and a second blocking semiconductor layer on the first blocking semiconductor layer and doped with a second conductive impurity at a second concentration.

The display device may further include a depletion reduction layer that includes a semiconductor layer doped with the second conductive impurity at the second concentration, wherein the current blocking layer may be on the depletion reduction layer.

An impurity doping concentration of the first blocking semiconductor layer, an impurity doping concentration of the second blocking semiconductor layer, and an impurity doping concentration of the depletion reduction layer may be 1×10¹⁷ cm⁻³ to 1×10²⁰cm⁻³.

### BRIEF DESCRIPTION OF DRAWINGS

The above and other aspects, features, and advantages of one or more embodiments will be more apparent from the following description taken in conjunction with the accompanying drawings, in which:

FIG. 1 is a schematic cross-sectional view of a light-emitting device according to one or more embodiments;

FIG. 2 is a diagram illustrating an example of an electrode structure of the light-emitting device shown in FIG. 1;

FIG. 3 is a schematic diagram of a first PN junction layer and a second PN junction layer;

FIG. 4 is a schematic cross-sectional view of a light-emitting device according to one or more embodiments;

FIG. 5 is a diagram illustrating an example of an electrode structure of the light-emitting device shown in FIG. 4;

FIG. 6 is a schematic cross-sectional view of a light-emitting device according to one or more embodiments;

FIG. 7 is a diagram illustrating an example of an electrode structure of the light-emitting device shown in FIG. 6;

FIG. 8 is a diagram illustrating a function of a depletion reduction layer;

FIG. 9 shows simulation results regarding leakage current reduction effects in a case where a current blocking layer is applied and a case where no current blocking layer is applied;

FIG. 10 is a schematic cross-sectional view of a light-emitting device according to one or more embodiments;

FIG. 11 is a diagram illustrating an example of an electrode structure of the light-emitting device shown in FIG. 10;

FIG. 12 is a schematic diagram of one or more embodiments of a display device;

FIG. 13 is a block diagram of an electronic device including a display, according to one or more embodiments;

FIG. 14 shows a mobile device as an example application of an electronic device, according to one or more embodiments;

FIG. 15 shows a head-up display device for a vehicle as an example application of an electronic device, according to one or more embodiments;

FIG. 16 shows augmented reality glasses or virtual reality glasses as an example application of an electronic device, according to one or more embodiments;

FIG. 17 shows a large signage as an example application of an electronic device, according to one or more embodiments; and

FIG. 18 shows a wearable display as an example application of an electronic device, according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

In recent years, technologies of applying light-emitting devices, such as microLED, to displays have been significantly developed, and televisions in which the microLED is applied have begun to be released. Further, efforts have been made to apply microLED in augmented reality devices. In displays for augmented reality devices, significantly small microLED display chips (or panels) are fabricated monolithically at the wafer level without a process of transferring microLED as in television displays. In television displays, the size of one pixel is tens to hundreds of micrometers, but in small or ultra-small displays, such as displays for augmented reality devices, the size of one pixel is very small, such as several micrometers.

In order to express color images on a display, one pixel (color pixel) includes red-green-blue (RGB) sub-pixels. Array structures of RGB sub-pixels include horizontal array structures and vertical array structures. The horizontal array structure is a method in which RGB sub-pixels are horizontally arranged, and the vertical array structure is a method in which RGB sub-pixels are vertically arranged. In the horizontal array structure, each of the sub-pixels may be referred to as a microLED. In the vertical array structure, the microLED is a monolithic RGB microLED with integrated RGB sub-pixels.

For a given size of a color pixel, the horizontal array structure requires sub-pixels be fabricated in a smaller size than the vertical array structure, and thus the horizontal process is relatively difficult. In the vertical array structure, sub-pixels are vertically arranged, and thus the vertical process is relatively difficult. However, in the vertical array structure, sub-pixels may be fabricated in a greater size than in the horizontal array structure, thus exhibiting greater efficiency (external quantum efficiency (EQE)) than in the horizontal array structure.

Leakage current between sub-pixels may be a difficulty in microLED with the vertical array structure. For example, in a structure where a blue sub-pixel, a green sub-pixel, and a red sub-pixel are sequentially stacked, leakage current may flow between an upper electrode of the blue sub-pixel and a lower electrode of the green sub-pixel, and/or between an upper electrode of the green sub-pixel and a lower electrode of the red sub-pixel. The leakage current may deteriorate light emission efficiency of the microLED.

One or more embodiments provide a light-emitting device in which a PN junction structure is used to reduce or prevent leakage current between sub-pixels, a display device employing the light-emitting device, and a method of fabricating the light-emitting device.

Below, embodiments of the light-emitting device and the display device employing the light-emitting device are described in detail with reference to the accompanying drawings. In the drawings below, the same reference characters denote the same elements, and a size of each element in the drawings may be exaggerated for clarity and convenience of description. In addition, embodiments described below are merely examples, and various modifications may be made to these embodiments.

Below, terms, such as “above” or “on”, may include not only elements which are directly above in contact, but also elements which are above in a non-contact manner. Singular expressions include plural expressions, unless the context clearly indicates otherwise. In addition, when a part “comprises” or “includes” an element, this does not mean that the part excludes other elements, but rather that the part may include other elements, unless otherwise specifically described.

The use of the term “the” and similar referential terms may refer to both the singular and the plural. Unless operations of a method are explicitly described in a particular order or in a different order, these operations may be performed in any suitable order and are not necessarily limited to the order described.

The connections or lack of connections between lines depicted in the drawings are merely illustrative of functional connections and/or physical or circuit connections, and may be represented in an actual device as alternative or additional various functional connections, physical connections, or circuit connections.

Any use of examples or example terms is merely intended to elaborate technical ideas and is not intended to limit the scope of the disclosure unless otherwise defined by the claims.

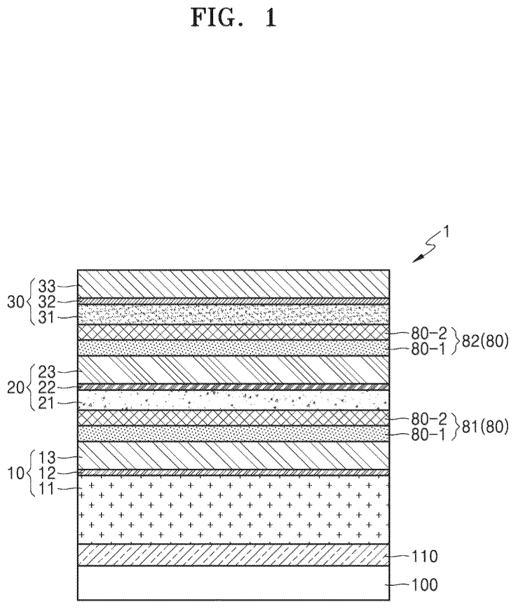

FIG. 1 is a schematic cross-sectional view of a light-emitting device 1 according to one or more embodiments. The light-emitting device 1 of the present embodiment is a vertically stacked light-emitting device including a plurality of sub-pixels that are vertically stacked. For example, the light-emitting device 1 may be a monolithic color microLED.

Referring to FIG. 1, the light-emitting device 1 may include a plurality of light emission structures which are vertically stacked. The light-emitting device 1 may correspond to one pixel in the display device, and the plurality of light emission structures may respectively correspond to vertically stacked sub-pixels which form one pixel. Each of the plurality of light emission structures may include a first conductive semiconductor layer, an active layer, and a second conductive semiconductor layer which are sequentially stacked.

The plurality of light emission structures may include Group III-V nitride semiconductor materials. For example, Group III-V nitride semiconductor materials may include gallium nitride (GaN), indium gallium nitride (InGaN), aluminum indium gallium nitride (AlInGaN), aluminum gallium indium phosphide (AlGaInP), or the like. For example, the plurality of light emission structures may include GaN-based semiconductor materials. Each of the plurality of light emission structures may have a structure in which a first conductive semiconductor layer, an active layer having a quantum well structure, and a second conductive semiconductor layer are sequentially stacked. The band gap energy may be controlled and an emission wavelength band may be determined depending on a composition ratio of indium (In) in a material layer including In in the active layer.

The plurality of light emission structures may emit light of different wavelengths. According to one or more embodiments, the plurality of light emission structures may include a first light emission structure 10, a second light emission structure 20, and a third light emission structure 30 which are sequentially stacked. According to one or more embodiments, the first light emission structure 10 may constitute a lower layer. The second light emission structure 20 may be stacked on the first light emission structure 10, and the third light emission structure 30 may be stacked on the second light emission structure 20 opposite to the first light emissions structure 10 in a vertical direction. The third light emission structure 30 may be a top layer based on a direction of light emission.

For example, the first, second, and third light emission structures 10, 20, and 30 may be formed on a substrate 100. The substrate 100 is a growth substrate for semiconductor single crystal growth, and for example, a silicon (Si) substrate, a silicon carbide (SiC) substrate, a sapphire substrate, or the like may be used. In addition, various substrates including materials suitable for growth of a light emission structure to be formed, e.g., aluminum nitride (AlN), aluminum gallium nitride (AlGaN), zinc oxide (ZnO), gallium arsenide (GaAs), magnesium aluminum oxide (MgAl₂O₄), magnesium oxide (MgO), lithium aluminum oxide (LiAlO₂), lithium gallium oxide (LiGaO₂), or GaN, may be used. A buffer layer 110 necessary for epitaxial growth of a light emission structure may be provided on a surface of the substrate 100, and a light emission structure may grow on the buffer layer 110.

The first light emission structure 10 may include a first conductive semiconductor layer 11, an active layer 12 having a quantum well structure, and a second conductive semiconductor layer 13, which are sequentially stacked. The first conductive semiconductor layer 11 may be a semiconductor layer, e.g., a GaN layer doped with first-type impurity. The active layer 12 may be a layer which emits light through electron-hole recombination. The active layer 12 may be formed by growing on the first conductive semiconductor layer 11. The active layer 12 may have a single quantum well structure or a multi quantum well structure. For example, the active layer 12 may have a multi quantum well structure created by periodically changing x, y, and z values in AlₓGa_{y}In_{z}N to control the band gap. For example, a quantum well layer and a barrier layer may be paired in the form of InGaN/InGaN, InGaN/AlGaN, or InGaN/InAlGaN to form a single quantum well structure, and a multi quantum well structure may be formed by stacking pairs of quantum well layers and barrier layers a plurality of times. The band gap energy may be controlled and an emission wavelength band may be adjusted depending on a composition ratio of indium (In) in a material layer including In in the active layer 12. The second conductive semiconductor layer 13 may be formed on the active layer 12. The second conductive semiconductor layer 13 may be a semiconductor layer, e.g., a GaN layer doped with second-type impurity. For example, the first-type impurity may be an n-type impurity and the second-type impurity may be a p-type impurity. As another example, the first-type impurity may be a p-type impurity and the second-type impurity may be an n-type impurity. N-type impurities may include Si, germanium (Ge), selenium (Se), tellurium (Te), or the like. P-type impurities may include magnesium (Mg), zinc (Zn), beryllium (Be), or the like. According to one or more embodiments, the first-type impurity may be an n-type impurity and the second-type impurity may be a p-type impurity. In this case, the first conductive semiconductor layer 11 may be an n-GaN layer and the second conductive semiconductor layer 13 may be a p-GaN layer. The active layer 12 may have a multi quantum well structure. The quantum well layer may include InGaN and the barrier layer may include GaN.

The second light emission structure 20 may include a first conductive semiconductor layer 21, an active layer 22 having a multi quantum well structure, and a second conductive semiconductor layer 23, which are sequentially stacked. The descriptions of the first conductive semiconductor layer 11, the active layer 12, and the second conductive semiconductor layer 13 of the first light emission structure 10 may be applicable to the first conductive semiconductor layer 21, the active layer 22, and the second conductive semiconductor layer 23 of the second light emission structure 20. According to one or more embodiments, the first-type impurity may be an n-type impurity and the second-type impurity may be a p-type impurity. In this case, the first conductive semiconductor layer 21 may be an n-GaN layer and the second conductive semiconductor layer 23 may be a p-GaN layer. The active layer 22 may have a multi quantum well structure. The quantum well layer may include InGaN and the barrier layer may include GaN.

The third light emission structure 30 may include a first conductive semiconductor layer 31, an active layer 32 having a multi quantum well structure, and a second conductive semiconductor layer 33, which are sequentially stacked. The descriptions of the first conductive semiconductor layer 11, the active layer 12, and the second conductive semiconductor layer 13 of the first light emission structure 10 may be applicable to the first conductive semiconductor layer 31, the active layer 32, and the second conductive semiconductor layer 33 of the third light emission structure 30. According to one or more embodiments, the first-type impurity may be an n-type impurity and the second-type impurity may be a p-type impurity. In this case, the first conductive semiconductor layer 31 may be an n-GaN layer and the second conductive semiconductor layer 33 may be a p-GaN layer. The active layer 32 may have a multi quantum well structure. The quantum well layer may include InGaN and the barrier layer may include GaN.

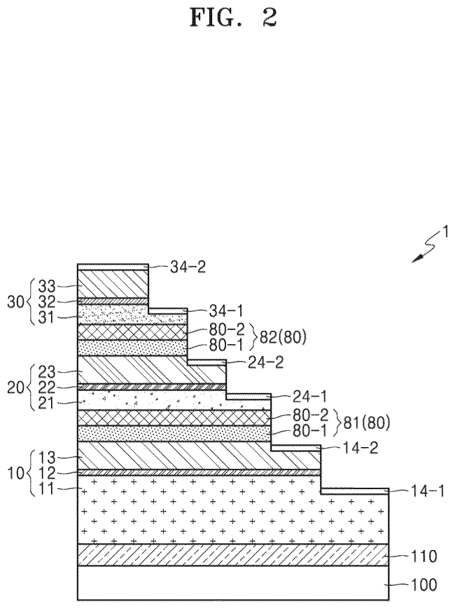

FIG. 2 is a diagram illustrating an example of an electrode structure of the light-emitting device 1 shown in FIG. 1. Referring to FIG. 2, a plurality of first electrodes 14-1, 24-1, and 34-1 in contact with the first conductive semiconductor layers 11, 21, and 31 of the plurality of light emission structures, i.e., the respective first, second, and third light emission structures 10, 20, and 30, and a plurality of second electrodes 14-2, 24-2, and 34-2 in contact with the second conductive semiconductor layers 13, 23, and 33 of the plurality of light emission structures, i.e., the respective first, second, and third light emission structures 10, 20, and 30, may be provided. For example, the first, second, and third light emission structures 10, 20, and 30 may be etched in a stair shape so that the first conductive semiconductor layers 11, 21, and 31 and the second conductive semiconductor layers 13, 23, and 33 may be exposed. The plurality of first electrodes 14-1, 24-1, and 34-1 and the plurality of second electrodes 14-2, 24-2, and 34-2 may be arranged on exposed surfaces of the first conductive semiconductor layers 11, 21, and 31 and the second conductive semiconductor layers 13, 23, and 33.

For example, the third light emission structure 30 on the top layer of the plurality of light emission structures located on the light emission side of the light-emitting device 1 may emit red light, e.g., light in a wavelength range of 630±20 nm. For example, the first light emission structure 10 and the second light emission structure 20 may emit blue light (e.g., light in a wavelength range of 460±20 nm and green light (e.g., light in a wavelength range of 530±20 nm, respectively. For example, an In concentration of a quantum well layer of the first light emission structure 10 may be about 13% to about 18%, an In concentration of a quantum well layer of the second light emission structure 20 may be about 20% to about 25%, and an In concentration of a quantum well layer of the third light emission structure 30 may be about 30 % to about 35%. For example, the first light emission structure 10 and the second light emission structure 20 may emit green light and blue light, respectively.

The third light emission structure 30 on the top layer of the plurality of light emission structures located on the light emission side of the light-emitting device 1 may emit blue light, e.g., light in a wavelength range of 460±20 nm. For example, the first light emission structure 10 and the second light emission structure 20 may emit red light (e.g., light in a wavelength range of 630±20 nm and green light (e.g., light in a wavelength range of 530±20 nm, respectively. For example, the first light emission structure 10 and the second light emission structure 20 may emit green light and red light, respectively.

A driving voltage may be applied between the first conductive semiconductor layer and the second conductive semiconductor layer of each of the plurality of light emission structures through the plurality of first electrodes and the plurality of second electrodes, thereby allowing at least one light emission structure among the plurality of light emission structures to emit light. When a current passes through the active layer between the first conductive semiconductor layer and the second conductive semiconductor layer of each light emission structure, relatively high light emission efficiency may be obtained. For example, in two adjacent light emission structures, leakage current may flow between the second conductive semiconductor layer of the lower light emission structure and the first conductive semiconductor layer of the upper light emission structure. Leakage current may cause deterioration of light emission efficiency, and thus leakage current may need to be reduced or prevented.

According to one or more embodiments, a current blocking layer 80 may be arranged between at least one of the adjacent pair of light emissions structures among the plurality of light emission structures, thereby reducing or preventing leakage current. The current blocking layer 80 according to one or more embodiments may include at least one PN junction layer which is arranged in a reverse bias state between two adjacent light emission structures. The PN junction layer may include first and second blocking semiconductor layers 80-1 and 80-2 doped with different conductive impurities. The current blocking layer 80 may include Group III-V nitride semiconductor materials. For example, Group III-V nitride semiconductor materials may include GaN, InGaN, AlInGaN, AlGaInP, or the like. The current blocking layer 80 may include the same semiconductor material as the plurality of light emission structures 10, 20, and 30. For example, the first blocking semiconductor layer 80-1 may include the same semiconductor material as the first conductive semiconductor layer of an adjacent light emission structure (e.g., the light emission structure located below the first blocking semiconductor layer 80-1). The first blocking semiconductor layer 80-1 may be doped with first conductive impurities at a relatively low concentration. The second blocking semiconductor layer 80-2 may include the same semiconductor material as the second conductive semiconductor layer of an adjacent light emission structure (e.g., the light emission structure located above the second blocking semiconductor layer 80-2). The second blocking semiconductor layer 80-2 may be doped with second conductive impurities at a low concentration. According to the above, the plurality of light emission structures 10, 20, and 30 and the current blocking layer 80 may be formed by an epitaxial growth while minimizing crystal defects, such as lattice discrepancy, between the plurality of light emission structures 10, 20, and 30 and the current blocking layer 80. According to one or more embodiments, for example, the plurality of light emission structures 10, 20, and 30 and the current blocking layer 80 may include GaN-based semiconductor materials. Below, a case is described in which the first conductive semiconductor layers 11, 21, and 31 and the second conductive semiconductor layers 13, 23, and 33 of the plurality of light emission structures 10, 20, and 30 are n-GaN layers and p-GaN layers, respectively, and the first and second blocking semiconductor layers 80-1 and 80-2 constituting the current blocking layer 80 are GaN layers which are doped with n-type impurities and p-type impurities at a low concentration, respectively. N-type impurities may include silicon (Si), germanium (Ge), selenium (Se), telluride (Te), or the like. P-type impurities may include magnesium (Mg), zinc (Zn), beryllium (Be), or the like. An impurity doping concentration of the first and second blocking semiconductor layers 80-1 and 80-2 may be about 1×10¹⁷cm⁻³ to about 1×10²⁰cm⁻³. Considering the thinning of the light-emitting device 1, a thickness of each of the first and second blocking semiconductor layers 80-1 and 80-2 may be less than or equal to 500 nm.

Referring to FIG. 1, the current blocking layer 80 may include a first PN junction layer 81 interposed between the first light emission structure 10 and the second light emission structure 20 and a second PN junction layer 82 interposed between the second light emission structure 20 and the third light emission structure 30. The first PN junction layer 81 may constitute a PN junction layer arranged in a reverse bias state between the second conductive semiconductor layer 13 of the first light emission structure 10 and the first conductive semiconductor layer 21 of the second light emission structure 20. The first PN junction layer 81 may include the first blocking semiconductor layer 80-1 doped with first conductive impurities at a relatively low concentration and the second blocking semiconductor layer 80-2 doped with second conductive impurities at a relatively low concentration. The first blocking semiconductor layer 80-1 may be stacked on the second conductive semiconductor layer 13 of the first light emission structure 10, and the second blocking semiconductor layer 80-2 may be stacked on a first blocking semiconductor layer 80-1 to constitute the first PN junction layer 81. The second PN junction layer 82 may constitute a PN junction layer arranged in a reverse bias state between the second conductive semiconductor layer 23 of the second light emission structure 20 and the first conductive semiconductor layer 31 of the third light emission structure 30. The second PN junction layer 82 may include the first blocking semiconductor layer 80-1 doped with first conductive impurities at a relatively low concentration and the second blocking semiconductor layer 80-2 doped with second conductive impurities at a relatively low concentration. The first blocking semiconductor layer 80-1a may be stacked on the second conductive semiconductor layer 23 of the second light emission structure 20, and the second blocking semiconductor layer 80b may be stacked on the first blocking semiconductor layer 80a to constitute the second PN junction layer 82.

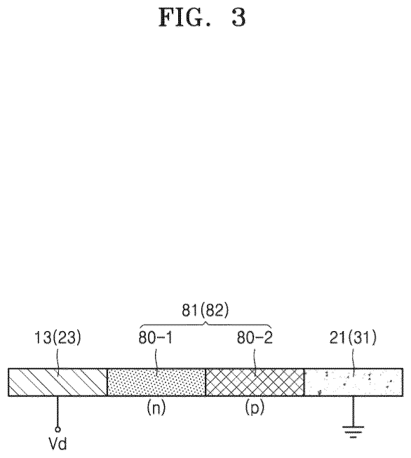

FIG. 3 is a schematic diagram of the first PN junction layer 81 and the second PN junction layer 82. Referring to FIG. 3, the first PN junction layer 81 may be interposed between the second conductive semiconductor layer 13 of the first light emission structure 10 and the first conductive semiconductor layer 21 of the second light emission structure 20. The second PN junction layer 82 may be interposed between the second conductive semiconductor layer 23 of the second light emission structure 20 and the first conductive semiconductor layer 31 of the third light emission structure 30.

For example, because the second conductive semiconductor layer 13 of the first light emission structure 10 is a p-GaN layer, the first blocking semiconductor layer 80a of the first PN junction layer 81 may be an n-GaN layer doped with n-type impurities at a relatively low concentration. A doping concentration of n-type impurities in the first blocking semiconductor layer 80a may be about 1×10¹⁷cm⁻³ to about 1×10²⁰cm⁻³. The second blocking semiconductor layer 80b of the first PN junction layer 81 may be a p-GaN layer doped with p-type impurities at a relatively low concentration. A doping concentration of p-type impurities in the second blocking semiconductor layer 80b may be about 1×10¹⁷cm⁻³ to about 1×10²⁰cm⁻³. A thickness of each of the first and second blocking semiconductor layers 80a and 80b of the first PN junction layer 81 may be 500 nm or less.

For example, because the second conductive semiconductor layer 23 of the second light emission structure 20 is a p-GaN layer, the first blocking semiconductor layer 80a of the second PN junction layer 82 may be an n-GaN layer doped with n-type impurities at a relatively low concentration. The doping concentration of n-type impurities in the first blocking semiconductor layer 80a may be about 1×10¹⁷ cm⁻³ to about 1×10²⁰cm⁻³. The second blocking semiconductor layer 80b of the second PN junction layer 82 may be a p-GaN layer doped with p-type impurities at a relatively low concentration. The doping concentration of p-type impurities in the second blocking semiconductor layer 80b may be about 1×10¹⁷ cm⁻³ to about 1×10²⁰cm⁻³. The thickness of each of the first and second blocking semiconductor layers 80a and 80b of the second PN junction layer 82 may be 500 nm or less.

When the first light emission structure 10 emits light, a driving voltage Vd may be applied to the second conductive semiconductor layer 13 of the first light emission structure 10, and the first conductive semiconductor layer 11 of the first light emission structure 10 may be grounded. The current may flow from the second conductive semiconductor layer 13 of the first light emission structure 10 to the first conductive semiconductor layer 11 of the first light emission structure 10 through the active layer 12, and light may be generated in the active layer 12. When the second conductive semiconductor layer 13 of the first light emission structure 10 and the first conductive semiconductor layer 21 of the second light emission structure 20 are in direct contact with each other, the first conductive semiconductor layer 21 of the second light emission structure 20 may be grounded so that leakage current may flow between the second conductive semiconductor layer 13 of the first light emission structure 10 and the first conductive semiconductor layer 21 of the second light emission structure 20, thereby deteriorating light emission efficiency of the first light emission structure 10.

According to one or more embodiments, the first PN junction layer 81 formed by the first blocking semiconductor layer 80a and the second blocking semiconductor layer 80b may be interposed between the first light emission structure 10 and the second light emission structure 20. As shown in FIG. 3, from the perspective of the first PN junction layer 81, the driving voltage Vd may act as a reverse bias voltage. Accordingly, a current path between the second conductive semiconductor layer 13 of the first light emission structure 10 and the first conductive semiconductor layer 21 of the second light emission structure 20 may be blocked by the first PN junction layer 81, so that leakage current may be reduced or blocked.

The second PN junction layer 82 formed by the first blocking semiconductor layer 80-1 and the second blocking semiconductor layer 80-2 may be interposed between the second light emission structure 20 and the third light emission structure 30. From the perspective of the second PN junction layer 82, the driving voltage Vd applied to the second conductive semiconductor layer 23 of the second light emission structure 20 may act as a reverse bias voltage. Accordingly, the current path between the second conductive semiconductor layer 23 of the second light emission structure 20 and the first conductive semiconductor layer 31 of the third light emission structure 30 may be blocked by the second PN junction layer 82, so that leakage current may be reduced or blocked.

As shown in FIG. 2, the current blocking layer 80 may not be in contact with the plurality of first electrodes 14-1, 24-1, and 34-1 and the plurality of second electrodes 14-2, 24-2, and 34-2. Referring to FIG. 3, an etching thickness of the second conductive semiconductor layer 13 of the first light emission structure 10 may be determined so that the second electrode 14-2 does not come into contact with and is spaced apart from the first blocking semiconductor layer 80-1 of the first PN junction layer 81 by taking into account a thickness of the second electrode 14-2. Similarly, an etching thickness of the second conductive semiconductor layer 23 of the second light emission structure 20 may be determined so that the second electrode 24-2 does not come into contact with and is spaced apart from the first blocking semiconductor layer 80-1 of the second PN junction layer 82 by taking into account the thickness of the second electrode 24-2.

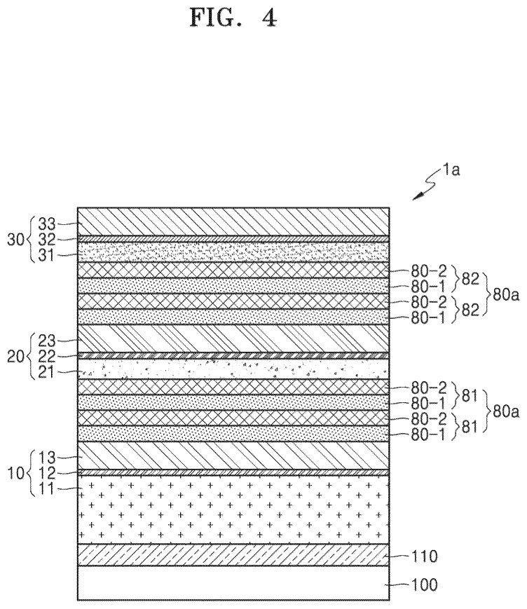

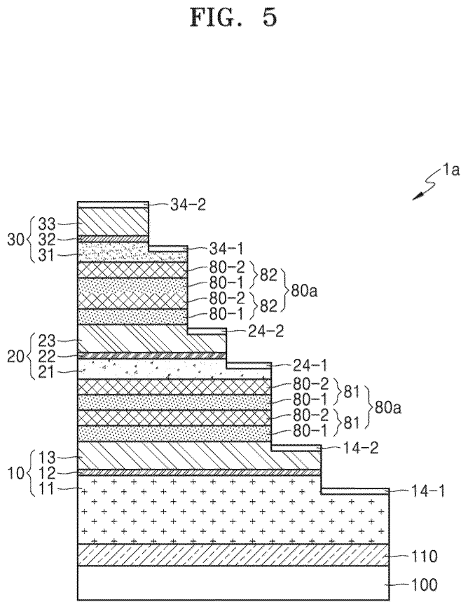

FIG. 4 is a schematic cross-sectional view of a light-emitting device 1a according to one or more embodiments. FIG. 5 is a diagram illustrating an example of an electrode structure of the light-emitting device 1a shown in FIG. 4. The light-emitting device 1a of one or more embodiments is a vertically stacked light-emitting device in which a plurality of sub-pixels are vertically stacked. For example, the light-emitting device 1a may be a monolithic color microLED. The light-emitting device 1a according to one or more embodiments differs from the light-emitting device 1 described above with reference to FIGS. 1 to 3 in that the light-emitting device 1a includes a plurality of PN junction layers. The above descriptions of the light-emitting device 1 may be equally applied to the light-emitting device 1a unless the descriptions of the light-emitting device 1 conflict with the nature of the light-emitting device 1a. Below, elements which perform the same function are indicated with the same reference characters, redundant descriptions are omitted, and differences are mainly described.

Referring to FIGS. 4 and 5, the current blocking layer 80a may include a plurality of PN junction layers. The plurality of PN junction layers are stacked on top of each other. For example, two first PN junction layers 81 may be interposed between the first light emission structure 10 and the second light emission structure 20. The two first PN junction layers 81 may be connected in series with each other between the first light emission structure 10 and the second light emission structure 20. From the perspective of the two first PN junction layers 81, the driving voltage Vd described above may act as a reverse bias. Therefore, leakage current between the second conductive semiconductor layer 13 of the first light emission structure 10 and the first conductive semiconductor layer 21 of the second light emission structure 20 may be more effectively prevented. The number of first PN junction layers 81 is not limited to two and may be three or more.

Similarly, two second PN junction layers 82 may be interposed between the second light emission structure 20 and the third light emission structure 30. The two second PN junction layers 82 may be connected in series with each other between the second light emission structure 20 and the third light emission structure 30. From the perspective of the two second PN junction layers 82, the driving voltage Vd described above may act as a reverse bias. Therefore, leakage current between the second conductive semiconductor layer 23 of the second light emission structure 20 and the first conductive semiconductor layer 31 of the third light emission structure 30 may be more effectively prevented. The number of second PN junction layers 82 is not limited to two and may be three or more.

Accordingly, when the first conductive semiconductor layers 11, 21, and 31 are n-type semiconductor layers and the second conductive semiconductor layers 13, 23, and 33 are p-type semiconductor layers, the current blocking layer 80 or 80a may have a structure of (np) x N, where N is a natural number greater than or equal to 1. In addition, when the first conductive semiconductor layers 11, 21, and 31 are p-type semiconductor layers and the second conductive semiconductor layers 13, 23, and 33 are n-type semiconductor layers, the current blocking layer 80 or 80a may have a structure of (pn)×N, where N is a natural number greater than or equal to 1.

As shown in FIG. 5, the current blocking layer 80a may not be in contact with the plurality of first electrodes 14-1, 24-1, and 34-1 and the plurality of second electrodes 14-2, 24-2, and 34-2. Referring to FIG. 5, an etching thickness of the second conductive semiconductor layer 13 of the first light emission structure 10 may be determined so that the second electrode 14-2 does not come into contact with and is spaced apart from the first blocking semiconductor layer 80-1 of the first PN junction layer 81 located at the bottom among the two first PN junction layers 81, by taking into account the thickness of the second electrode 14-2. Similarly, an etching thickness of the second conductive semiconductor layer 23 of the second light emission structure 20 may be determined so that the second electrode 24-2 does not come into contact with and is spaced apart from the first blocking semiconductor layer 80-1 of the second PN junction layer 82 located at the bottom among the two second PN junction layers 82, by taking into account the thickness of the second electrode 24-2.

One or more embodiments of a method of fabricating the light-emitting devices 1 and 1a is briefly described with reference to FIGS. 1, 2, 4, and 5.

First, the first light emission structure 10 may be formed on the substrate 100. If necessary, the buffer layer 110 may be provided on a surface of the substrate 100. For example, the first light emission structure 10 may include Group III-V nitride semiconductor materials. For example, Group III-V nitride semiconductor materials may include GaN, InGaN, AlInGaN, AlGaInP, or the like. For example, the first light emission structure 10 may be formed by epitaxially growing a GaN-based semiconductor material. The first conductive semiconductor layer 11 may be, for example, an n-GaN layer doped with n-type impurities. The active layer 12 is a layer which emits light through electron-hole recombination, and may have a single quantum well or multi quantum well structure, as described above. For example, a quantum well layer and a barrier layer may form a quantum well structure by being paired in the form of InGaN/GaN, InGaN/InGaN, InGaN/AlGaN, or InGaN/InAlGaN, and the band gap energy may be controlled depending on the composition ratio of In in a material layer including In, so that the light emission wavelength band may be adjusted. The second conductive semiconductor layer 13 may be a p-GaN layer doped with p-type impurities. P-type impurities may include Mg, Zn, Be, or the like. The first light emission structure 10 may be formed by hydride vapor phase epitaxy (HVPE), molecular beam epitaxy (MBE), metal organic vapor phase epitaxy (MOVPE), metal organic chemical vapor deposition (MOCVD), other known methods, or any combinations thereof.

Next, the current blocking layer 80 including at least one first PN junction layer 81 may be formed on the first light emission structure 10. For example, a first blocking semiconductor layer 80-1 including a semiconductor doped with first conductive impurities at a relatively low concentration may be formed on the second conductive semiconductor layer 13. The doping concentration of first conductive impurities in the first blocking semiconductor layer 80-1 may be about 1×10¹⁷cm⁻³ to about 1×10²⁰cm⁻³. Next, a second blocking semiconductor layer 80-2 including a semiconductor doped with first conductive impurities at a relatively low concentration may be formed on the second conductive semiconductor layer 13. The doping concentration of second conductive impurities in the second blocking semiconductor layer 80-2 may be about 1×10¹⁷cm⁻³ to about 1×10²⁰cm⁻³. For example, the first PN junction layer 81 may include Group III-V nitride semiconductor materials. For example, Group III-V nitride semiconductor materials may include GaN, InGaN, AlInGaN, AlGaInP, or the like. For example, the first PN junction layer 81 may be formed by epitaxially growing a GaN-based semiconductor material. The first blocking semiconductor layer 80-1 may include the same semiconductor material as the first conductive semiconductor layer 11. The second blocking semiconductor layer 80-2 may include the same semiconductor material as the second conductive semiconductor layer 13. For example, the first blocking semiconductor layer 80-1 may be an n-GaN layer doped with n-type impurities at a relatively low concentration and the second blocking semiconductor layer 80-2 may be a p-GaN layer doped with p-type impurities at a relatively low concentration. According to the above, the discrepancy of lattice constant between the first light emission structure 10 and the first PN junction layer 81 may be minimized, thereby enabling stable epitaxial growth of the first PN junction layer 81.

Next, the second light emission structure 20 may be formed on the current blocking layer 80, i.e., the first PN junction layer 81. Regarding a method of forming the second light emission structure 20, the method of forming the first light emission structure 10 described above may be applied.

Next, the current blocking layer 80 including at least one second PN junction layer 82 may be formed on the second light emission structure 20. Regarding a method of forming the second PN junction layer 82, the method of forming the first PN junction layer 81 described above may be applied.

Next, the third light emission structure 30 may be formed on the current blocking layer 80, i.e., the second PN junction layer 82. Regarding a method of forming the third light emission structure 30, the method of forming the first light emission structure 10 described above may be applied.

Next, the first, second, and third light emission structures 10, 20, and 30 may be etched to partially expose the first conductive semiconductor layers 11, 21, and 31 and the second conductive semiconductor layers 13, 23, and 33, and a conductive material may be deposited on surfaces of the exposed first conductive semiconductor layers 11, 21, and 31 and the exposed second conductive semiconductor layers 13, 23, and 33, so as to form the first electrodes 14-1, 24-1, and 34-1 and the second electrodes 14-2, 24-2, and 34-2, respectively. Here, the first electrodes 14-1, 24-1, and 34-1 and the second electrodes 14-2, 24-2, and 34-2 may be formed not to come into contact with and be spaced apart from the current blocking layers 80, i.e., the first and second PN junction layers 81 and 82.

By the process described above, the light-emitting device 1 shown in FIGS. 1 and 2 may be fabricated. In addition, the light-emitting device 1a shown in FIGS. 4 and 5 may be fabricated by forming the plurality of first PN junction layers 81 and the plurality of second PN junction layers 82.

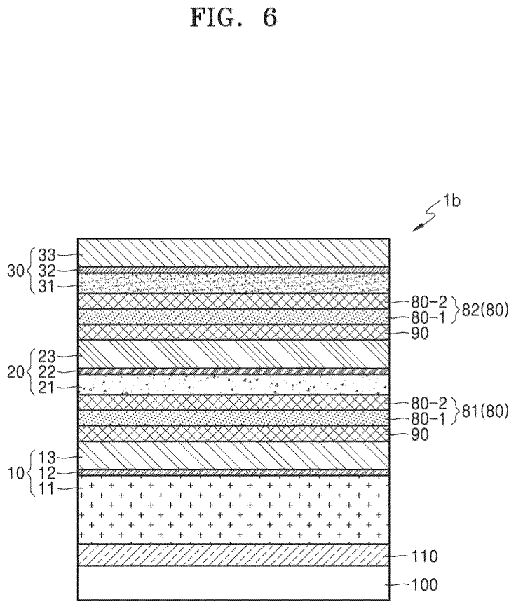

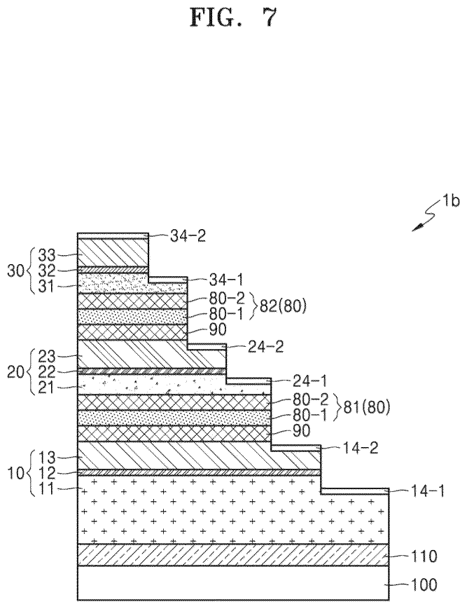

FIG. 6 is a schematic cross-sectional view of a light-emitting device 1b according to one or more embodiments. FIG. 7 is a diagram illustrating an example of an electrode structure of the light-emitting device 1b shown in FIG. 6. The light-emitting device 1b of one or more embodiments is a vertically stacked light-emitting device in which a plurality of sub-pixels are vertically stacked. For example, the light-emitting device 1b may be a monolithic color microLED. The light-emitting device 1b according to one or more embodiments differs from the light-emitting device 1 described above with reference to FIGS. 1 to 3 in that the light-emitting device 1b includes a depletion reduction layer 90. The above descriptions of the light-emitting device 1 may be equally applied to the light-emitting device 1b unless the descriptions of the light-emitting device 1 conflict with the nature of the light-emitting device 1b. Below, elements which perform the same function are indicated with the same reference characters, redundant descriptions are omitted, and differences are mainly described.

Referring to FIGS. 6 and 7, the light-emitting device 1b according to one or more embodiments may further include the depletion reduction layer 90. The depletion reduction layer 90 may be arranged between at least one pair of adjacent light-emitting devices among a plurality of light-emitting devices. The current blocking layer 80 may be stacked on the depletion reduction layer 90. The depletion reduction layer 90 may be in direct contact with the second conductive semiconductor layer of the light emission structure located below the depletion reduction layer 90. The depletion reduction layer 90 may be a semiconductor layer which is doped, at a relatively low concentration, with impurities having the same conductive type as the second conductive semiconductor layer of the light emission structure located below the depletion reduction layer 90. For example, the depletion reduction layer 90 may be a semiconductor layer doped with second conductive impurities at a relatively low concentration. The impurity doping concentration of the depletion reduction layer 90 may be about 1×10¹⁷cm⁻³ to about 1×10²⁰cm⁻³. Considering the thinning of the light-emitting device 1b, the thickness of the depletion reduction layer 90 may be less than or equal to 500 nm.

The depletion reduction layer 90 may include Group III-V nitride semiconductor materials. For example, Group III-V nitride semiconductor materials may include GaN, InGaN, AlInGaN, AlGaInP, or the like. The depletion reduction layer 90 may include the same semiconductor material as the plurality of light emission structures 10, 20, and 30. For example, the depletion reduction layer 90 may include the same semiconductor material as the second conductive semiconductor layer of an adjacent light emission structure (e.g., the light emission structure located below the depletion reduction layer 90). According to the above, the plurality of light emission structures 10, 20, and 30 and the depletion reduction layer 90 may be formed by an epitaxial growth while minimizing crystal defects, such as lattice discrepancy, between the plurality of light emission structures 10, 20, and 30 and the depletion reduction layer 90. For example, the plurality of light emission structures 10, 20, and 30 and the current blocking layer 80 may include GaN-based semiconductor materials. The depletion reduction layer 90 may be a GaN layer doped with second conductive impurities. When the second conductive semiconductor layers 13, 23, and 33 of the first and second light emission structures 10 and 20 are p-GaN layers, the depletion reduction layer 90 may be a p-GaN layer doped with p-type impurities at a relatively low concentration, e.g., at a doping concentration of about 1×10¹⁷ to about 1×10²⁰cm⁻³. As a result, the depletion reduction layer 90 may include the same semiconductor material as the second blocking semiconductor layer 80-2.

Referring to FIG. 7, the current blocking layer 80 and the depletion reduction layer 90 may not be in contact with the plurality of first electrodes 14-1, 24-1, and 34-1 and the plurality of second electrodes 14-2, 24-2, and 34-2. To this end, an etching thickness of the second conductive semiconductor layer 13 of the first light emission structure 10 may be determined so that the second electrode 14-2 does not come into contact with and is spaced apart from the depletion reduction layer 90, by taking into account the thickness of the second electrode 14-2. Similarly, an etching thickness of the second conductive semiconductor layer 23 of the second light emission structure 20 may be determined so as to not come into contact with and is spaced apart from the depletion reduction layer 90, by taking into account the thickness of the second electrode 24-2.

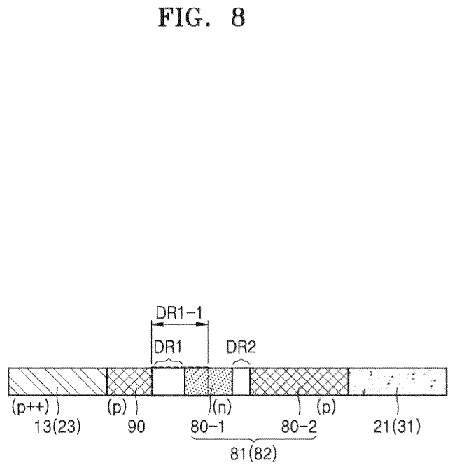

FIG. 8 is a diagram illustrating a function of the depletion reduction layer 90. Referring to FIG. 8, the depletion reduction layer 90 and the first PN junction layer 81 may be sequentially arranged between the second conductive semiconductor layer 13 of the first light emission structure 10 and the first conductive semiconductor layer 21 of the second light emission structure 20. The depletion reduction layer 90 and the second PN junction layer 82 may be sequentially arranged between the second conductive semiconductor layer 23 of the second light emission structure 20 and the first conductive semiconductor layer 31 of the third light emission structure 30. For example, the second conductive semiconductor layer 13 of the first light emission structure 10, the depletion reduction layer 90, the first blocking semiconductor layer 80-1, the second blocking semiconductor layer 80-2, and the first conductive semiconductor layer 21 of the second light emission structure 20 may be provided in that order.

For example, because the second conductive semiconductor layer 13 of the first light emission structure 10 is a p-GaN layer, the depletion reduction layer 90 may be a p-GaN layer doped with p-type impurities at a relatively low concentration. The first blocking semiconductor layer 80-1 of the first PN junction layer 81 may be an n-GaN layer doped with n-type impurities at a relatively low concentration. The second blocking semiconductor layer 80-2 of the first PN junction layer 81 may be a p-GaN layer doped with p-type impurities at a relatively low concentration.

When the first light emission structure 10 emits light, the driving voltage Vd may be applied to the second conductive semiconductor layer 13 of the first light emission structure 10, and the first conductive semiconductor layer 11 of the first light emission structure 10 may be grounded. The current may flow from the second conductive semiconductor layer 13 of the first light emission structure 10 to the first conductive semiconductor layer 11 of the first light emission structure 10 through the active layer 12, and light may be generated in the active layer 12. In order to block leakage current between the second conductive semiconductor layer 13 of the first light emission structure 10 and the first conductive semiconductor layer 21 of the second light emission structure 20, the depletion reduction layer 90 and the current blocking layer 80 including the first PN junction layer 81 may be interposed between the first and second light emission structures 10 and 20.

When two semiconductors of different conductive types form a junction, a depletion region may be formed at the boundary area of the two semiconductors. When the depletion reduction layer 90 is not applied, the second conductive semiconductor layer 13/first blocking semiconductor layer 80-1/second blocking semiconductor layer 80-2 may be sequentially stacked to form a P/N/P junction. Accordingly, as indicated by a dotted line, a depletion region DR1-1 may be formed at the boundary area of the second conductive semiconductor layer 13/first blocking semiconductor layer 80-1, and a depletion region DR2 may be formed at the boundary area of the first blocking semiconductor layer 80-1/second blocking semiconductor layer 80-2. An area between the depletion region DR1-1 and the depletion region DR2 may be an area which actually blocks current (current blocking area), and as the width of the current blocking area increases, the possibility of leakage current due to punch-through may decrease and stable current blocking may be possible.

In order to ensure the width of the current blocking area, the width of the depletion regions DR1-1 and DR2 may be reduced. As described above, the width of the depletion region may depend on the doping concentration of a semiconductor. Because an impurity doping concentration of the second conductive semiconductor layer 13 is higher that an impurity doping concentration of the first blocking semiconductor layer 80-1, the depletion region DR1-1 with a relatively large width may be formed at the boundary area of the second conductive semiconductor layer 13 and the first blocking semiconductor layer 80-1. In addition, because the depletion region DR2 may be formed by the first blocking semiconductor layer 80-1 and the second blocking semiconductor layer 80-2 which are doped at a relatively low concentration, the width of the depletion region DR2 may be relatively small compared to that of the depletion region DR1-1. Therefore, the width of the depletion region DR1-1 may be reduced.

In consideration of the above, according to the disclosure, the depletion reduction layer 90 may be interposed between the second conductive semiconductor layer 13 and the first PN junction layer 81. The depletion reduction layer 90 may be a semiconductor layer doped with p-type impurities at a relatively low concentration. The width of the depletion region DR1 formed by the first blocking semiconductor layer 80-1 may be less than the width of the depletion region DR1-1 formed by the second conductive semiconductor layer 13 and the first blocking semiconductor layer 80-1. Thus, the current blocking area with a relatively large width may be ensured, reducing the possibility of current leakage due to punch-through and enabling stable current blocking.

For example, because the second conductive semiconductor layer 23 of the second light emission structure 20 is a p-GaN layer, the depletion reduction layer 90 may be a p-GaN layer doped with p-type impurities at a relatively low concentration. The first blocking semiconductor layer 80-1 of the second PN junction layer 82 may be an n-GaN layer doped with n-type impurities at a relatively low concentration. When the second light emission structure 20 emits light, the driving voltage Vd may be applied to the second conductive semiconductor layer 23 of the second light emission structure 20, and the first conductive semiconductor layer 21 of the second light emission structure 20 may be grounded. The current may flow from the second conductive semiconductor layer 23 of the second light emission structure 20 to the first conductive semiconductor layer 21 of the second light emission structure 20 through the active layer 22, and light may be generated in the active layer 22. According to the disclosure, the depletion reduction layer 90 may be interposed between the second conductive semiconductor layer 23 and the second PN junction layer 82. The depletion reduction layer 90 may be a semiconductor layer doped with p-type impurities at a relatively low concentration. The width of the depletion region DR1 formed by the first blocking semiconductor layer 80-1 of the PN junction layer 82 may be less than the width of the depletion region DR1-1 formed by the second conductive semiconductor layer 13 and the first blocking semiconductor layer 80-1 of the second PN junction layer 82. Thus, the current blocking area with a relatively large width may be ensured, reducing the possibility of current leakage due to punch-through and enabling stable current blocking.

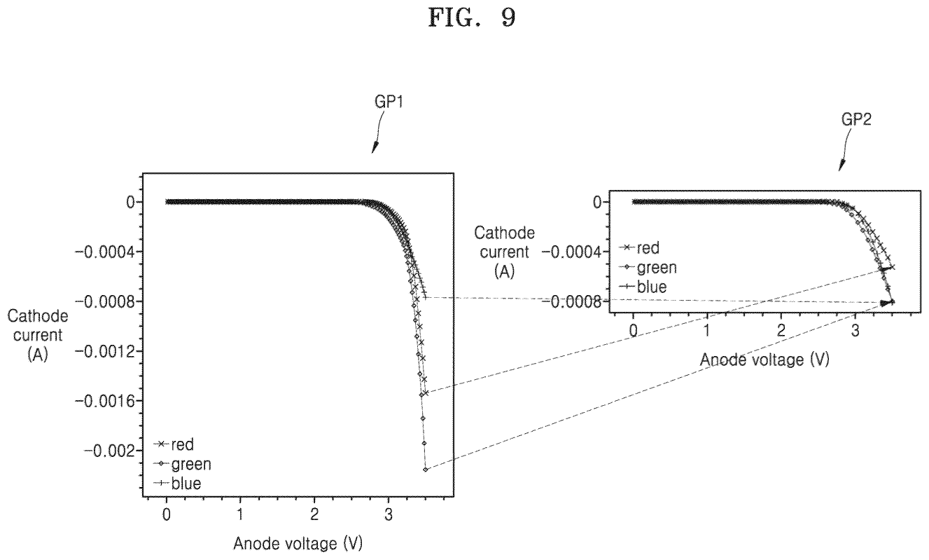

FIG. 9 shows simulation results regarding leakage current reduction effects in a case where a current blocking layer 80 is applied and a case where no current blocking layer 80 is applied. In FIG. 9, a graph GP1 is a graph showing leakage current in a case where the current blocking layer 80 is not applied, and a graph GP2 is a graph showing leakage current in a case where the current blocking layer 80 and the depletion reduction layer 90 are applied. In the graphs GP1 and GP2, a horizontal axis indicates the anode voltage and a vertical axis indicates the cathode current. The graph GP2 is shown with the vertical axis ratio matched with that of the graph GP1. The first electrodes 14-1, 24-1, and 34-1 of the first, second, and third light emission structures 10, 20, and 30 may be grounded, and a driving voltage of 3.5 V may be applied to the second electrodes 14-2, 24-2, and 34-2. As shown in FIG. 9, there is almost no leakage current in the first light emission structure 10, but when the current blocking layer 80 and the depletion reduction layer 90 are applied, it can be seen that leakage current is reduced in the second light emission structure 20 and the third light emission structure 30 as compared to the case where the current blocking layer 80 and the depletion reduction layer 90 are not applied.

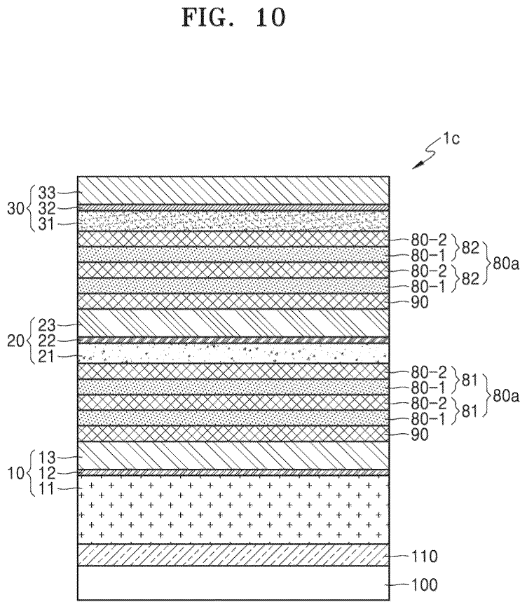

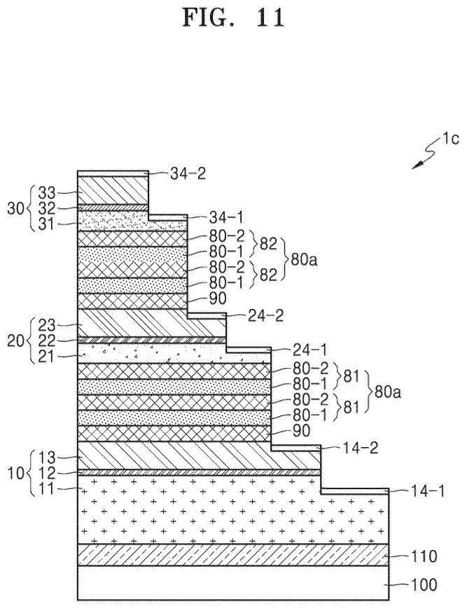

FIG. 10 is a schematic cross-sectional view of a light-emitting device 1c according to one or more embodiments. FIG. 11 is a diagram illustrating an example of an electrode structure of the light-emitting device 1c shown in FIG. 10. The light-emitting device 1c of one or more embodiments is a vertically stacked light-emitting device in which a plurality of sub-pixels are vertically stacked. For example, the light-emitting device 1c may be a monolithic color microLED. The light-emitting device 1c according to one or more embodiments is an integrated form of the light-emitting device 1a shown in FIGS. 4 and 5 and the light-emitting device 1b shown in FIGS. 6 and 7. Thus, the above descriptions of the light-emitting device 1a and the light-emitting device 1b may be applied equally to the light-emitting device 1c unless the descriptions of the light-emitting device 1a and the light-emitting device 1b conflict with the nature of the light-emitting device 1c. Below, elements which perform the same function are indicated with the same reference characters, redundant descriptions are omitted, and differences are mainly described.

Referring to FIGS. 10 and 11, in the light-emitting device 1c according to one or more embodiments, the depletion reduction layer 90 and the current blocking layer 80a which is stacked on the depletion reduction layer 90 may be arranged in at least one between a plurality of light-emitting structures. The current blocking layer 80a may include two or more PN junction layers which are sequentially stacked. For example, the depletion reduction layer 90 and the two first PN junction layers 81 may be arranged between the first light-emitting device 10 and the second light-emitting device 20. The number of first PN junction layers 81 is not limited to two and may be three or more. The depletion reduction layer 90 and the two second PN junction layers 82 may be arranged between the second light-emitting device 20 and the third light-emitting device 30. The number of second PN junction layers 82 is not limited to two and may be three or more.

Accordingly, when the first conductive semiconductor layers 11, 21, and 31 are n-type semiconductor layers and the second conductive semiconductor layers 13, 23, and 33 are p-type semiconductor layers, the current blocking layer 80a may have a structure of p+(np)×N, where N is a natural number greater than or equal to 1. In addition, when the first conductive semiconductor layers 11, 21, and 31 are p-type semiconductor layers and the second conductive semiconductor layers 13, 23, and 33 are n-type semiconductor layers, the current blocking layer 80 may have a structure of n+(pn)×N, where N is a natural number greater than or equal to 1.

One or more embodiments of a method of fabricating the light-emitting devices 1b and 1c is briefly described with reference to FIGS. 7, 8, 10, and 11. Below, a method of forming the first, second, and third light emission structures 10, 20, and 30 and the first and second PN junction layers 81 and 82 is same as that described in the embodiment of the method of fabricating the light-emitting devices 1 and 1a, and thus redundant descriptions thereof are omitted.

First, the first light emission structure 10 may be formed on the substrate 100. If necessary, the buffer layer 110 may be provided on a surface of the substrate 100. Next, the depletion reduction layer 90 may be formed on the first light emission structure 10. For example, the depletion reduction layer 90 including a semiconductor doped with second conductive impurities at a relatively low concentration may be formed on the second conductive semiconductor layer 13. The doping concentration of second conductive impurities in the depletion reduction layer 90 may be about 1×10¹⁷ cm⁻³ to about 1×10²⁰cm⁻³. Next, the first PN junction layer 81 may be formed on the depletion reduction layer 90. For example, the depletion reduction layer 90 may include Group III-V nitride semiconductor materials. For example, Group III-V nitride semiconductor materials may include GaN, InGaN, AlInGaN, AlGaInP, or the like. For example, the depletion reduction layer 90 may be formed by epitaxially growing a GaN-based semiconductor material. The depletion reduction layer 90 may include the same semiconductor material as the second conductive semiconductor layer 13. For example, the depletion reduction layer 90 may be a p-GaN layer doped with p-type impurities at a relatively low concentration. According to the above, the discrepancy of lattice constant between the light emission structure 10, the depletion reduction layer 90, and the first PN junction layer 81 may be minimized, thereby enabling and increasing stability of epitaxial growth of the depletion reduction layer 90 and the first PN junction layer 81.

Next, a process of forming the second light emission structure 20 on the current blocking layer 80, i.e., the first PN junction layer 81, and a process of sequentially forming the depletion reduction layer 90, the second PN junction layer 82, and the third light emission structure 30 on the second light emission structure 20 may be performed.

Next, the first, second, and third light emission structures 10, 20, and 30 may be etched to partially expose the first conductive semiconductor layers 11, 21, and 31 and the second conductive semiconductor layers 13, 23, and 33, and a conductive material may be deposited on surfaces of the exposed first conductive semiconductor layers 11, 21, and 31 and the exposed second conductive semiconductor layers 13, 23, and 33, so as to form the first electrodes 14-1, 24-1, and 34-1 and the second electrodes 14-2, 24-2, and 34-2, respectively. Here, the first electrodes 14-1, 24-1, and 34-1 and the second electrodes 14-2, 24-2, and 34-2 may be formed not to come into contact with and be spaced apart from the depletion reduction layers 90 and the current blocking layers 80, i.e., the first and second PN junction layers 81 and 82.

By the process described above, the light-emitting device 1b shown in FIGS. 6 and 7 may be fabricated. In addition, by forming the plurality of first PN junction layers 81 and the plurality of second PN junction layers 82 may be formed on the depletion reduction layers 90, respectively, the light-emitting device 1c shown in FIGS. 10 and 11 may be fabricated.

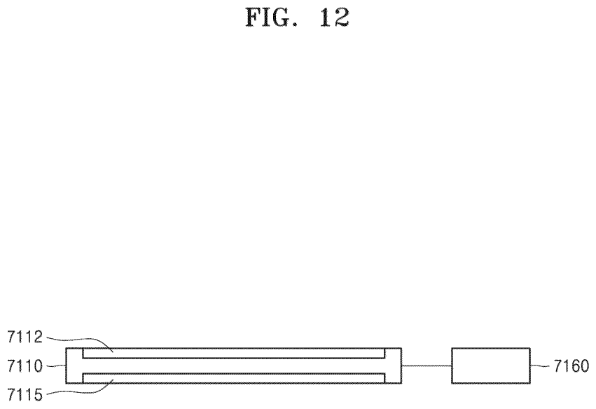

FIG. 12 is a schematic diagram of one or more embodiments of a display device. Referring to FIG. 12, the display device may include a display panel 7110 and a controller 7160. The display panel 7110 may have a light emission structure 7112 and a driving circuit 7115 which switches the light emission structure 7112 on and off. The light emission structure 7112 may include the plurality of light-emitting devices described above with reference to FIGS. 1 to 11. For example, the plurality of light-emitting devices may be arranged in a two-dimensional array. The driving circuit 7115 may have a plurality of switching devices for individually switching the plurality of light-emitting devices on and off. The controller 7160 may input an on-off switching signal for the plurality of light-emitting devices to the driving circuit 7115 according to an image signal.

FIG. 13 is a block diagram of an electronic device 8201 including a display, according to one or more embodiments. Referring to FIG. 13, the electronic device 8201 may be provided in a network environment 8200. In the network environment 8200, the electronic device 8201 may communicate with another electronic device 8202 through a first network 8298 (short-range wireless communication network or the like) or may communicate with another electronic device 8204 and/or a server 8208 through a second network 8299 (long-distance wireless communication network or the like). The electronic device 8201 may communicate with the electronic device 8204 through the server 8208. The electronic device 8201 may include a processor 8220, a memory 8230, an input device 8250, an audio output device 8255, a display device 8260, an audio module 8270, a sensor module 8276, an interface 8277, a haptic module 8279, a camera module 8280, a power management module 8288, a battery 8289, a communication module 8290, a subscriber identification module 8296, and/or an antenna module 8297. In the electronic device 8201, some of these elements may be omitted or other elements may be added. Some of the elements may be implemented as one integrated circuit. For example, the sensor module 8276 (e.g., a fingerprint sensor, an iris sensor, an illumination sensor, or the like) may be implemented embedded in the display device 8260 (e.g., a display or the like).

The processor 8220 may execute software (e.g., a program 8240, or the like) to control one or more other elements (e.g., hardware and software elements or the like) of the electronic device 8201 connected to the processor 8220 and perform various data processing or operations. As a part of data processing or operation, the processor 8220 may load commands and/or data received from other elements (e.g., the sensor module 8276, the communication module 8290, or the like) on a volatile memory 8232, process the commands and/or data stored in the volatile memory 8232, and store resulting data in a non-volatile memory 8234. The processor 8220 may include a main processor 8221 (e.g., a central processing unit, an application processor, or the like) and an auxiliary processor 8223 (e.g., a graphics processing device, an image signal processor, a sensor hub processor, a communication processor, or the like) which is operable independently of or together with the main processor 8221. The auxiliary processor 8223 may use less power than the main processor 8221 and may perform specialized functions.

The auxiliary processor 8223 may control functions and/or states associated with some elements (e.g., the display device 8260, the sensor module 8276, the communication module 8290, or the like) among elements of the electronic device 8201, in lieu of the main processor 8221 while the main processor 8221 is in an inactive state (sleep state), or together with the main processor 8221 while the main processor 8221 is in an active state (application running state). The auxiliary processor 8223 (e.g., an image signal processor, a communication processor, or the like) may also be implemented as a part of another element (e.g., the camera module 8280, the communication module 8290, or the like) functionally related to the auxiliary processor 8223.

The memory 8230 may store various data required by the elements of the electronic device 8201 (e.g., the processor 8220, the sensor module 8276, or the like). For example, the data may include software (e.g., the program 8240, or the like) and input data and/or output data for commands related to the software. The memory 8230 may include the volatile memory 8232 and/or the non-volatile memory 8234.

The program 8240 may be stored in the memory 8230 as software, and may include an operating system 8242, a middleware 8244, and/or an application 8246.

The input device 8250 may receive, from the outside (e.g., a user or the like) of the electronic device 8201, commands and/or data used for the elements (e.g., the processor 8220, or the like) of the electronic device 8201. The input device 8250 may include a remote controller, a microphone, a mouse, a keyboard, and/or a digital pen (e.g., a stylus pen).

The audio output device 8255 may output audio signals to the outside of the electronic device 8201. The audio output device 8255 may include a speaker and/or a receiver. The speaker may be used for general purposes, such as playing multimedia or recording, and the receiver may be used to receive incoming calls. The receiver may be coupled as a part of the speaker or may be implemented as a separate independent device.

The display device 8260 may visually provide information to the outside of the electronic device 8201. The display device 8260 may include a display, a hologram device, or a projector and control circuitry for controlling the device. The display device 8260 may include the display described with reference to FIG. 12. The display device 8260 may include touch circuitry configured to detect a touch, and/or sensor circuitry (e.g., a pressure sensor or the like) configured to measure intensity of a force generated by the touch.

The audio module 8270 may convert sound into an electrical signal, or vice versa. The audio module 8270 may obtain sound through the input device 8250 or may output sound through the audio module 8270 and/or a speaker and/or headphone of another electronic device (e.g., the electronic device 8202, or the like) directly or wirelessly connected to the electronic device 8201.

The sensor module 8276 may detect an operating state (e.g., power, temperature, or the like) of the electronic device 8201 or an external environment state (e.g., a user status or the like), and generate an electric signal and/or data value corresponding to the detected state. The sensor module 8276 may include a gesture sensor, a gyro sensor, a barometric sensor, a magnetic sensor, an acceleration sensor, a grip sensor, a proximity sensor, a color sensor, an infrared (IR) sensor, a biometric sensor, a temperature sensor, a humidity sensor, and/or an illumination sensor.

The interface 8277 may support one or more designated protocols which may be used by the electronic device 8201 to directly or wirelessly connect to other electronic devices (e.g., the electronic device 8202, or the like). The interface 8277 may include a High Definition Multimedia Interface (HDMI), a Universal Serial Bus (USB) interface, a Secure Digital (SD) card interface, and/or an audio interface.

A connection terminal 8278 may include a connector through which the electronic device 8201 may be physically connected to other electronic devices (e.g., the electronic device 8202, or the like). The connection terminal 8278 may include an HDMI connector, a USB connector, a SD card connector, and/or an audio connector (e.g., a headphone connector or the like).

The haptic module 8279 may convert an electrical signal into mechanical stimulus (e.g., vibration, motion, or the like) or electrical stimulus which the user may perceive through tactile or kinetic sensations. The haptic module 8279 may include a motor, a piezoelectric device, and/or an electrical stimulation device.

The camera module 8280 may capture still images and/or moving images. The camera module 8280 may include a lens assembly which includes one or more lenses, image sensors, image signal processors, and/or flashes. The lens assembly included in the camera module 8280 may collect light emitted from a subject of image capture.

The power management module 8288 may manage power supplied to the electronic device 8201. A power management module 8388 may be implemented as a part of a Power Management Integrated Circuit (PMIC).

The battery 8289 may supply power to the elements of the electronic device 8201. The battery 8289 may include a non-rechargeable primary cell, a rechargeable secondary cell, and/or a fuel cell.

The communication module 8290 may support establishment of a direct (wired) communication channel and/or a wireless communication channel between the electronic device 8201 and other electronic devices (e.g., the electronic device 8202, the electronic device 8204, the server 8208, or the like), and communication performed through the established communication channel. The communication module 8290 may be operated independently of the processor 8220 (e.g., an application processor or the like), and may include one or more communication processors which support direct communication and/or wireless communication. The communication module 8290 may include a wireless communication module 8292 (e.g., a cellular communication module, a short-range wireless communication module, a Global Navigation Satellite System (GNSS) communication module, or the like) and/or a wired communication module 8294 (e.g., a Local Area Network (LAN) communication module, a power line communication module, or the like). Any of these communication modules may communicate with other electronic devices through the first network 8298 (e.g., a short-range communication network, such as Bluetooth, Wi-Fi Direct, r Infrared Data Association (IrDA)) or the second network 8299 (e.g., a long-distance communication network, such as a cellular network, the Internet, or a computer network (LAN, Wide Area Network (WAN), or the like). Such various types of communication modules may be integrated as one element (e.g., a single chip or the like), or may be implemented as a plurality of separate elements (e.g., a plurality of chips). The wireless communication module 8292 may identify and authenticate the electronic device 8201 in a communication network, such as the first network 8298 and/or the second network 8299, by using subscriber information (e.g., International Mobile Subscriber Identity (IMSI) or the like) stored in the subscriber identification module 8296.

The antenna module 8297 may transmit or receive signals and/or power to or from the outside (other electronic devices or the like). An antenna may include a radiator including a conductive pattern on a substrate (e.g., a printed circuit board (PCB) or the like). The antenna module 8297 may include one antenna or a plurality of antennas. When a plurality of antennas are included, among the plurality of antennas, an antenna suitable for a communication scheme used in a communication network, such as the first network 8298 and/or the second network 8299, may be selected by the communication module 8290. Through the selected antenna, signals and/or power may be transmitted or received between the communication module 8290 and other electronic devices. In addition to the antenna, other components (e.g., a radio-frequency integrated circuit (RFIC) or the like) may be included as a part of the antenna module 8297.

Some of the elements may be connected to each other to exchange signals (e.g., commands, data, or the like) through a communication scheme (e.g., bus, General Purpose Input and Output (GPIO), Serial Peripheral Interface (SPI), Mobile Industry Processor Interface (MIPI), or the like).

The commands or data may be transmitted or received between the electronic device 8201 and the external electronic device 8204 through the server 8208 connected to the second network 8299. The other electronic devices 8202 and 8204 may be the same or a different type of device as the electronic device 8201. All or part of operations executed on the electronic device 8201 may be executed on one or more devices among the other electronic devices 8202, 8204, and 8208. For example, when the electronic device 8201 performs a certain function or service, the electronic device 8201 may request one or more other electronic devices to perform all or part of the function or service rather than executing the function or service itself. The one or more other electronic devices which receive the request may execute an additional function or service related to the request, and deliver a result of the execution to the electronic device 8201. To this end, cloud computing, distributed computing, and/or client-server computing technologies may be used.

The electronic device 8201 described above may be applied to various devices. The above-described various elements of the electronic device 8201 may be appropriately modified depending on the function of the device, and elements suitable for performing the function of the device may be added. Below, applications of the electronic device 8201 are described.

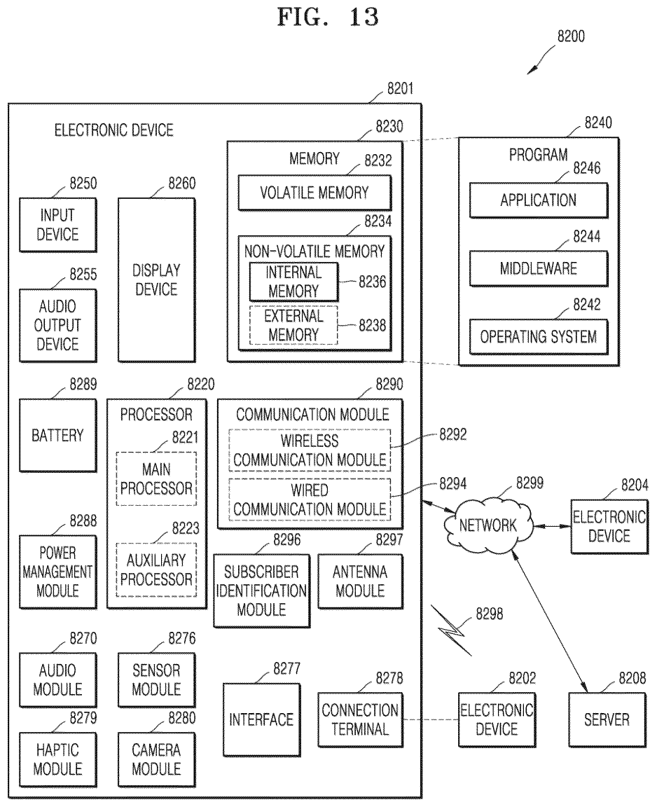

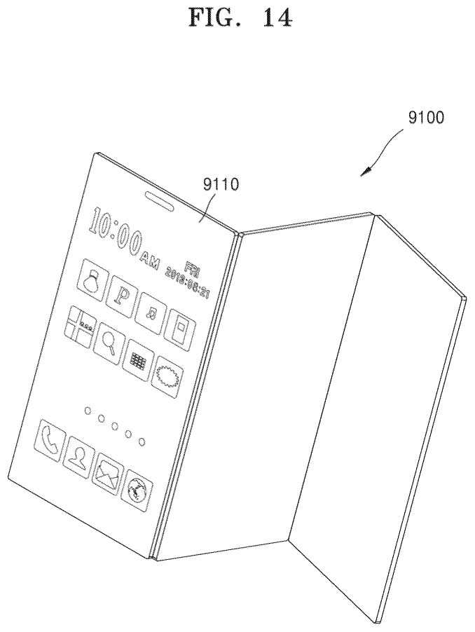

FIG. 14 shows a mobile device 9100 as an example application of an electronic device, according to one or more embodiments. The mobile device 9100 may include a display device 9110. The display device 9110 may include the display device described with reference to FIG. 12. The display device 9110 may have a foldable structure, for example, a multi-foldable structure.

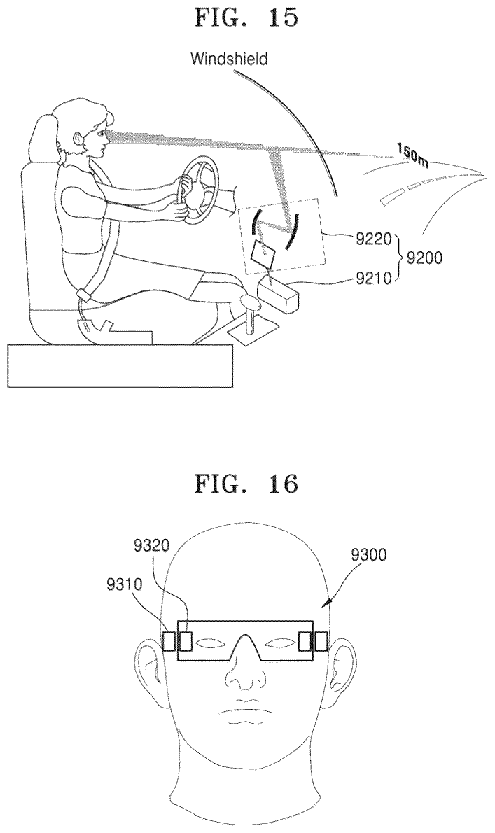

FIG. 15 shows a head-up display device 9200 for a vehicle as an example application of an electronic device, according to one or more embodiments. The head-up display device 9200 for a vehicle may include a display 9210 provided in an area of a vehicle, and an optical path changing member 9220 which changes an optical path so that a driver may see an image generated by the display 9210. The display device 9210 may include the display device described with reference to FIG. 12.

FIG. 16 shows augmented reality glasses or virtual reality glasses 9300 as an example application of an electronic device, according to one or more embodiments. The augmented reality glasses (or virtual reality glasses) 9300 may include a projection system 9310 forming an image, and an element 9320 which guides the image from the projection system 9310 into the user's eyes. The projection system 9310 may include the display device described with reference to FIG. 12.

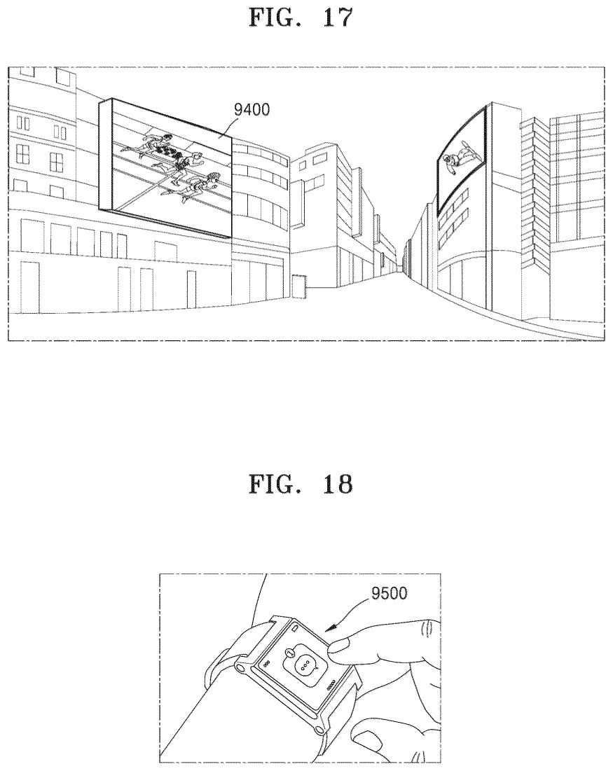

FIG. 17 shows a large signage 9400 as an example application of an electronic device, according to one or more embodiments. The signage 9400 may include the display device described with reference to FIG. 12. The signage 9400 may be used for outdoor advertising using a digital information display and may control advertising content or the like through a communication network. For example, the signage 9400 may be implemented through the electronic device described with reference to FIG. 13.

FIG. 18 shows a wearable display 9500 as an example application of an electronic device, according to one or more embodiments. The wearable display 9500 may include the display device described with reference to FIG. 12. The wearable display 9500 may be implemented through the electronic device described with reference to FIG. 13.

A light-emitting device or a display including the light-emitting device, according to one or more embodiments, may also be applied to various products, such as a rollable television (TV) or a stretchable display.

According to one or more embodiments, a light-emitting device in which a PN junction layer is interposed between a plurality of vertically stacked light emission structures forming sub-pixels, so as to reduce leakage current between the vertically stacked sub-pixels, and a display device employing the light-emitting device, may be implemented. In addition, a light-emitting device in which a depletion reduction layer and a PN junction layer are interposed between a plurality of light emission structures so as to reduce leakage current between vertically stacked sub-pixels, and a display device employing the light-emitting device, may be implemented.

It should be understood that embodiments described herein should be considered in a descriptive sense only and not for purposes of limitation. Descriptions of features or aspects within each embodiment should typically be considered as available for other similar features or aspects in other embodiments. While embodiments have been described with reference to the figures, it will be understood by those of ordinary skill in the art that various changes in form and details may be made therein without departing from the spirit and scope as defined by the following claims and their equivalents.

What is claimed is:

1. A light-emitting device comprising:
a plurality of light emission structures configured to emit light of different colors, wherein each light emission structure of the plurality of light emission structures comprises a first conductive semiconductor layer, an active layer having a quantum well structure, and a second conductive semiconductor layer; and
a current blocking layer between at least one pair of adjacent light emission structures of the plurality of light emission structures, the current blocking layer comprising at least one PN junction layer,
wherein the at least one PN junction layer comprises a first blocking semiconductor layer doped with a first conductive impurity at a first concentration and a second blocking semiconductor layer on the first blocking semiconductor layer and doped with a second conductive impurity at a second concentration.

2. The light-emitting device of claim 1, further comprising:
a plurality of first electrodes in contact with first conductive semiconductor layers included in the plurality of light emission structures, respectively; and
a plurality of second electrodes in contact with second conductive semiconductor layers included in the plurality of light emission structures, respectively,
wherein the current blocking layer is spaced apart from the plurality of first electrodes and the plurality of second electrodes.

3. The light-emitting device of claim 1, wherein a doping concentration of the first conductive impurity in the first blocking semiconductor layer and a doping concentration of the second conductive impurity in the second blocking semiconductor layer are each 1×10¹⁷ cm⁻³ to 1×10²⁰cm⁻³.

4. The light-emitting device of claim 1, wherein a thickness of the first blocking semiconductor layer is less than or equal to 500 nm.

5. The light-emitting device of claim 1, wherein a thickness of the second blocking semiconductor layer is less than or equal to 500 nm.

6. The light-emitting device of claim 1, wherein the at least one PN junction layer further comprises a plurality of PN junction layers.

7. The light-emitting device of claim 1, further comprising a depletion reduction layer that comprises a semiconductor layer doped with the second conductive impurity at a third concentration,
wherein the current blocking layer is on the depletion reduction layer.

8. The light-emitting device of claim 7, wherein a plurality of PN junction layers are on the depletion reduction layer.

9. The light-emitting device of claim 7, wherein a doping concentration of the second conductive impurity in the depletion reduction layer is 1×10¹⁷ cm⁻³ to 1×10²⁰cm⁻³.

10. The light-emitting device of claim 7, wherein a thickness of the depletion reduction layer is less than or equal to 500 nm.

11. The light-emitting device of claim 7, further comprising:
a plurality of first electrodes in contact with first conductive semiconductor layers included in the plurality of light emission structures, respectively; and
a plurality of second electrodes in contact with second conductive semiconductor layers included in the plurality of light emission structures, respectively,
wherein the depletion reduction layer is spaced apart from the plurality of first electrodes and the plurality of second electrodes.

12. The light-emitting device of claim 1, wherein the first blocking semiconductor layer comprises a semiconductor material same as a semiconductor material of the first conductive semiconductor layer.

13. The light-emitting device of claim 1, wherein the second blocking semiconductor layer comprises a semiconductor material same as a semiconductor material of the second conductive semiconductor layer.

14. A method of fabricating a light-emitting device, the method comprising:
forming a first light emission structure on a substrate, the first light emission structure comprising a first conductive semiconductor layer, an active layer, and a second conductive semiconductor layer;
forming at least one first PN junction layer on the first light emission structure, the at least one first PN junction layer comprising a first blocking semiconductor layer doped with a first conductive impurity at a first concentration and a second blocking semiconductor layer doped with a second conductive impurity at a second concentration; and
forming a second light emission structure on the at least one first PN junction layer, the second light emission structure comprising a first conductive semiconductor layer, an active layer, and a second conductive semiconductor layer.

15. The method of claim 14, wherein a doping concentration of the first conductive impurity in the first blocking semiconductor layer and a doping concentration of the second conductive impurity in the second blocking semiconductor layer are 1×10¹⁷ cm⁻³ to 1×10²⁰cm⁻³.

16. The method of claim 14, further comprising forming a depletion reduction layer on the first light emission structure, the depletion reduction layer comprising a semiconductor material doped with the second conductive impurity at the first concentration,
wherein the at least one first PN junction layer is formed on the depletion reduction layer.

17. The method of claim 16, wherein a doping concentration of the second conductive impurity in the depletion reduction layer is 1×10¹⁷ cm⁻³ to 1×10²⁰cm⁻³.

18. A display device comprising:
a display panel comprising a plurality of light-emitting devices and a driving circuit configured to switch the plurality of light-emitting devices on and off; and
at least one processor configured to input an on-off switching signal of the plurality of light-emitting devices to the driving circuit based on an image signal,
wherein each of the plurality of light-emitting devices comprises:
a plurality of light emission structures configured to emit light of different colors, wherein each of the plurality of light emission structures comprises a first conductive semiconductor layer, an active layer having a quantum well structure, and a second conductive semiconductor layer; and
a current blocking layer between at least one pair of adjacent light emission structures of the plurality of light emission structures, the current blocking layer comprising at least one PN junction layer,
wherein the at least one PN junction layer comprises a first blocking semiconductor layer doped with a first conductive impurity at a first concentration, and a second blocking semiconductor layer on the first blocking semiconductor layer and doped with a second conductive impurity at a second concentration.

19. The display device of claim 18, further comprising a depletion reduction layer that comprises a semiconductor layer doped with the second conductive impurity at a third concentration,
wherein the current blocking layer is on the depletion reduction layer.

20. The display device of claim 19, wherein an impurity doping concentration of the first blocking semiconductor layer, an impurity doping concentration of the second blocking semiconductor layer, and an impurity doping concentration of the depletion reduction layer are 1×10¹⁷ cm⁻³ to 1×10²⁰cm⁻³.
